(19) United States
(12) Patent Application Publication
(10) Pub. No.: US 2024/0332223 A1
(43) Pub. Date: Oct. 3, 2024

(54) Chip Die Substrate with Edge-Mounted Capacitors

(71) Applicant: NVIDIA Corporation, Santa Clara, CA (US)

(72) Inventors: Tracy Fu, Shenzhen (CN); Tiger Yan, Shenzhen (CN); Joey Cai, Shenzhen (CN); Zach Wang, Shenzhen (CN)

(73) Assignee: NVIDIA Corporation, Santa Clara, CA (US)

(21) Appl. No.: 18/596,003

(22) Filed: Mar. 5, 2024

(30) Foreign Application Priority Data
Mar. 31, 2023 (WO) PCT/CN2023/085403

(51) Int. Cl. H01L 23/64; H01L 23/00; H01L 23/50

(52) U.S. Cl. CPC H01L 23/642; H01L 23/50; H01L 24/08; H01L 24/16; H01L 2224/08146; H01L 2224/08155; H01L 2224/16148; H01L 2224/16157; H01L 2924/1205

(57) ABSTRACT

An integrated circuit die substrate has one or more capacitors attached to an edge surface of the substrate. The substrate has a top surface and a bottom surface, at least one of which includes a die mounting area, and at least one of which includes system interconnect terminals. A substrate edge surface is disposed along a peripheral end of the substrate and is oriented substantially orthogonally to the top and bottom surfaces. A pair of conductive edge terminals is disposed on the substrate edge surface. Each of the edge terminals is electrically coupled to a respective substrate conductor disposed on or inside the substrate. A capacitor is attached exteriorly to the substrate at the substrate edge surface such that terminals of the capacitor are electrically coupled to respective ones of the edge terminals. An integrated circuit die is attached at the die mounting area.

### BACKGROUND

Packaging techniques for integrated circuit chips have developed such that modern central processing unit (“CPU”) and graphics processing unit (“GPU”) packages include a substrate on which the integrated circuit die is mounted. A rectangular grid or array of connecting points is typically provided on the bottom side of the substrate to connect the circuitry of the integrated circuit die with the circuitry of a host system printed circuit board (“PCB”) through conductors inside the substrate. Examples of such grids or arrays of connecting points include pin grid arrays (“PGA”), ball grid arrays (“BGA”), land grid arrays (“LGA”), and the like. A substrate has a larger area than does an integrated circuit die, so inclusion of a substrate in the chip package makes more space available to accommodate the relatively large PGA pins, BGA solder balls, or LGA contact pads that must be placed on the package.

A common problem associated with integrated circuit packages, including CPU and GPU packages, is transient voltage drops that are associated with switching signals on the chip die. The current path associated with any switching signal presents an inductance, L. Any switching signal will therefore produce a transient voltage drop across this inductance in an amount proportional to its di/dt, since the voltage across an inductor, V_{L}, is equal to the product of the inductance and the di/dt. In other words, V_{L}=L*di/dt. To compensate for these transient voltage drops, designers place decoupling capacitors in close proximity to a chip package to absorb the transients by supplying short-term current demand with a nearby charge, thereby reducing the voltage drop on the signal path. The effectiveness of this technique increases with the size of the capacitance and the closeness of the capacitance to the affected signal. Decoupling capacitors can be very large, however, compared to the size of an integrated circuit die. Consequently, placement of the decoupling capacitors has become increasingly problematic because the area in close proximity to the chip package is already dense with PCB traces, pins, solder balls, and contact pads.

A need therefore exists for better techniques for disposing high-capacitance decoupling capacitors in close proximity to an integrated circuit chip die.

### BRIEF DESCRIPTION OF THE DRAWINGS

FIG. 1 is a top view of an integrated circuit die substrate with edge-mounted capacitors, in accordance with embodiments.

FIG. 2 is a sectional view of the integrated circuit die substrate of FIG. 1.

FIG. 3 is an expanded view of the area indicated in the sectional view of FIG. 2.

FIG. 4 is a sectional view of an integrated circuit die substrate with an edge-mounted capacitor oriented horizontally, in accordance with embodiments.

FIG. 5 is a closeup view of an integrated circuit die substrate with an edge-mounted capacitor wherein substrate edge terminals are electrically coupled to more than one substrate conductor, in accordance with embodiments.

FIGS. 6-8 are sectional views of further integrated circuit die substrates, illustrating various types of connectivity possible for capacitors mounted to edge surfaces of the substrates, in accordance with embodiments.

FIG. 9 is a top schematic view of an integrated circuit die substrate with edge-mounted capacitors, illustrating various further types of connectivity possible for the edge mounted capacitors, in accordance with embodiments.

FIG. 10 is a side view illustrating an integrated circuit die substrate with edge-mounted capacitors wherein the substrate is directly attached to a host system PCB in accordance with embodiments.

FIG. 11 is a side view illustrating an integrated circuit die substrate with edge-mounted capacitors wherein the substrate is attached to a host system PCB through a socket in accordance with embodiments.

FIG. 12 is a flow diagram illustrating an example method for manufacturing an integrated circuit die substrate with edge-mounted capacitors in accordance with embodiments.

### DETAILED DESCRIPTION

This disclosure describes multiple embodiments by way of example and illustration. It is intended that characteristics and features of all described embodiments may be combined in any manner consistent with the teachings, suggestions and objectives contained herein. Thus, phrases such as “in an embodiment,” “in one embodiment,” and the like, when used to describe embodiments in a particular context, are not intended to limit the described characteristics or features only to the embodiments appearing in that context.

The phrases “based on” or “based at least in part on” refer to one or more inputs that can be used directly or indirectly in making some determination or in performing some computation. Use of those phrases herein is not intended to foreclose using additional or other inputs in making the described determination or in performing the described computation. Rather, determinations or computations so described may be based either solely on the referenced inputs or on those inputs as well as others. The phrase “configured to” as used herein means that the referenced item, when operated, can perform the described function. In this sense an item can be “configured to” perform a function even when the item is not operating and is therefore not currently performing the function. Use of the phrase “configured to” herein does not necessarily mean that the described item has been modified in some way relative to a previous state. “Coupled” as used herein refers to a connection between items. Such a connection can be direct or can be indirect through connections with other intermediate items. Terms used herein such as “including,” “comprising,” and their variants, mean “including but not limited to.” Articles of speech such as “a,” “an,” and “the” as used herein are intended to serve as singular as well as plural references except where the context clearly indicates otherwise.

The terms “lands,” “pads,” and “terminals” may be used interchangeably herein. Each term refers to an electrically conductive element disposed on a surface of a component and configured to connect one or more conductors of the component to corresponding conductors of another component.

Chip Die Substrate with Edge-Mounted Capacitors

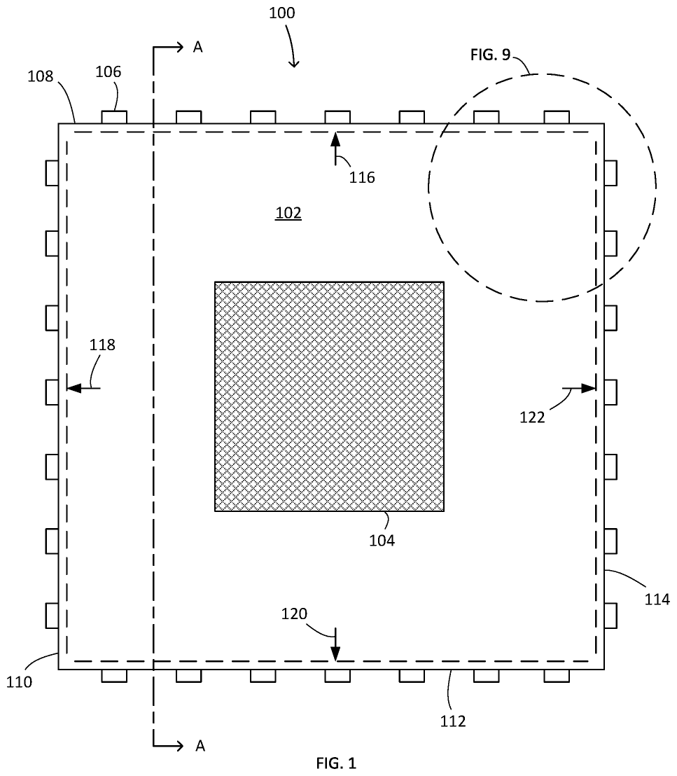

FIG. 1 is a top view of a substrate 100 according to an example embodiment. In this top view, a generally planar top surface 102 of the substrate is visible. The top surface includes a die mounting area 104. In other embodiments, the die mounting area may be disposed on a bottom surface of the substrate, or die mounting areas may be provided on both the top and the bottom surfaces of the substrate. The die mounting area is configured to receive an integrated circuit die (a “chip”) for electrical coupling of lands or pads on the die to conductors in the substrate using any of several known techniques, such as by direct soldering of die pads and substrate terminals in flip-chip fashion, or by wire bonding. The substrate may be constructed using any suitable materials, such as any of several known rigid or flexible resins, or with ceramics. Multiple capacitors 106 are shown mounted to the substrate on each of four edge surfaces 108, 110, 112, 114 of the substrate. The edge surfaces are disposed along respective peripheral ends 116, 118, 120, 122 of the substrate. In the illustrated embodiment, each capacitor is a surface mount capacitor, and each of the capacitors is identical to the others. In other embodiments, a mix of different types of capacitors may be used as appropriate to the application.

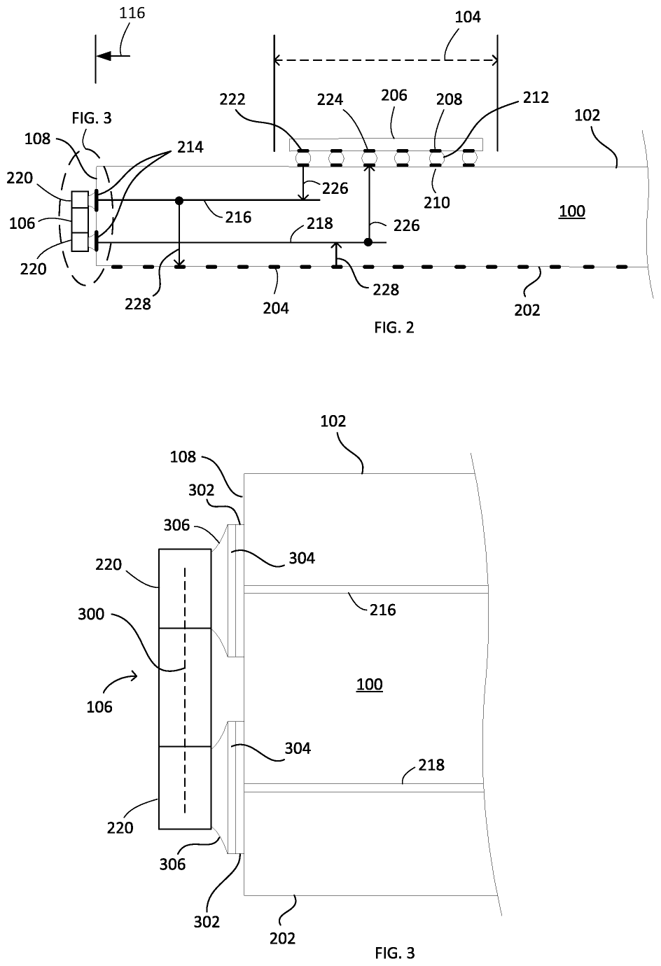

FIG. 2 is a partial sectional view taken along section A-A indicated in FIG. 1. For clarity of illustration, only peripheral end 116 of the substrate is shown in the drawing. It should be noted that the connectivity details illustrated in the figure are provided by way of example and not by way of limitation. In other embodiments, different types of connectivity may be implemented. In this sectional view, a generally planar bottom surface 202 of the substrate can be seen. Top surface 102 and bottom surface 202 are oriented substantially parallel to one another. Multiple electrically conductive system interconnect terminals 204 are disposed on the bottom surface, as shown. The system interconnect terminals are configured to interface with corresponding terminals on a PCB of a host system.

An integrated circuit die 206 is shown attached to the top surface of the substrate at the die mounting area. As was mentioned above, the die may be coupled to the substrate using any of several known techniques. For example, in a flip-chip embodiment such as the one illustrated, die pads 208 on the die may be electrically connected to corresponding pads 210 disposed on the substrate using solder balls 212. In other embodiments, different die mounting techniques may be used. By virtue of conductors disposed inside and/or on the substrate, circuitry on the integrated circuit die may be electrically coupled to circuitry on the PCB of a host system through the system interconnect terminals. It should be noted that, in other embodiments, the system interconnect terminals may be disposed on the top surface of the substrate instead of on the bottom surface, or may be disposed on both of the top and the bottom surfaces.

As can be seen in this sectional view, substrate edge surface 108 is oriented substantially orthogonally to the top surface and to the bottom surface of the substrate. A pair of conductive edge terminals 214 is disposed on the substrate edge surface. Each of the edge terminals is electrically coupled to a respective substrate conductor 216, 218. The substrate conductors may take a variety of forms, but are typically formed using metal planes disposed on one or more layers inside the material of the substrate. Such a metal plane may extend across an entire layer from one peripheral end of the substrate to another, or may occupy only a portion of a substrate layer, while another electrically independent metal plane may occupy another portion of the same layer. In still further embodiments, one or more of the substrate conductors may comprise a wire or trace formed inside the substrate or on an exterior surface of the substrate.

A capacitor 106 is attached exteriorly to the substrate at the substrate edge surface, as shown. Terminals 220 of the capacitor are electrically coupled to respective ones of the substrate conductors 216, 218.

In the illustrated embodiment, capacitor 106 is a surface mount capacitor. In other embodiments, other types of capacitors may be used. The term “surface mount” as used herein refers to an electronic component that is configured to be mounted to the surface of another component without the use of through holes. Typically, surface mounting is accomplished by means of terminals disposed on surfaces of each of the components to be connected. Such surface terminals typically take the form of generally planar metal contacts formed on the surface of the components themselves, but may also take the form of very short leads.

In the example embodiment shown in FIG. 2, capacitor 106 is electrically connected between die pads 222 and 224 through substrate conductors 216, 218 and vias 226 formed inside the substrate. Each of the substrate conductors is, in turn, electrically connected to a respective system interconnect terminal through vias 228. This connection scheme is shown by way of example only. In other embodiments, other connection schemes may be implemented.

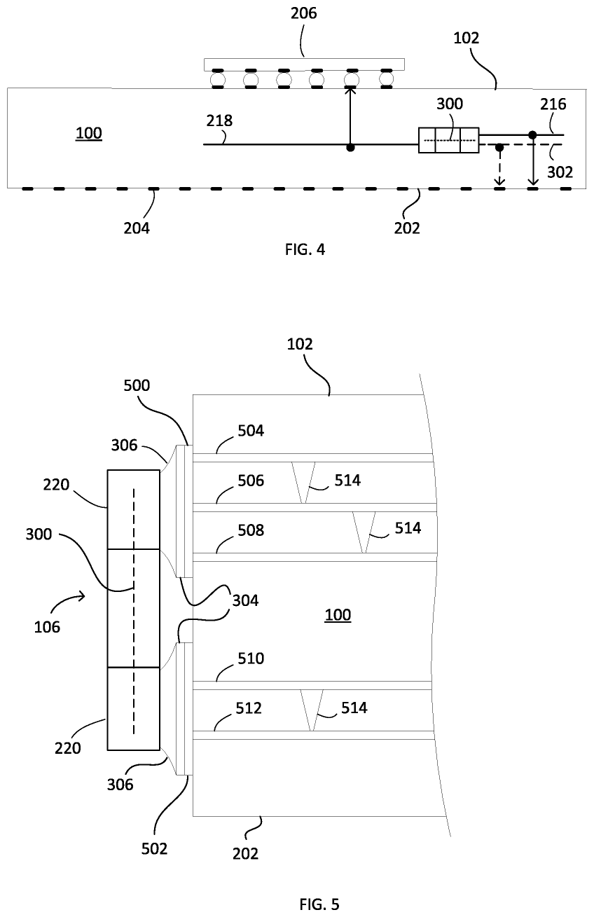

Edge-mounted capacitors 106 may be oriented in multiple different directions, as FIGS. 3 and 4 illustrate. In each of the embodiments illustrated in FIGS. 3 and 4, a capacitor 106 has electrical terminals 220 disposed at opposite ends of the capacitor body. The opposite ends define a capacitor axis 300 extending in the direction from one of the opposite ends to the other. In both of the embodiments of FIGS. 3 and 4, the capacitor axis is oriented substantially parallel to a plane defined by the substrate edge surface 108. In the embodiment of FIG. 3, the capacitor axis is oriented “vertically” with respect to the substrate—that is, oriented substantially perpendicular to a plane defined by the top surface 102 and to a plane defined by the bottom surface 202. In the embodiment of FIG. 4, however, a capacitor 106 is shown with its axis oriented “horizontally” with respect to the substrate—that is, oriented substantially parallel to the planes defined by the top and bottom surfaces of the substrate. In the vertical embodiments, the respective terminals of the capacitor may be electrically coupled to substrate conductors disposed on different layers of the substrate, as shown in FIG. 3. In the horizontal embodiments, the respective capacitor terminals may be electrically coupled to substrate conductors 216, 218 disposed on different layers of the substrate, or to electrically independent substrate conductors 218, 302 disposed on the same layer of the substrate. Other capacitor orientations with respect to the substrate, such as diagonal orientations, are also possible.

Referring again now to FIG. 3, an example technique for physically and electrically coupling a capacitor to a substrate edge surface is shown in more detail. In the example embodiment, a conductive edge terminal 302 may be formed on an exterior of the substrate edge surface and electrically coupled to a respective substrate conductor 216, 218, as shown. Edge terminals 302 may be formed using any of a variety of available techniques, including by metal deposition, by etching, or by plating inner surfaces of a through hole in the substrate and then removing a portion of the substrate and through hole to expose a portion of the plating. In the latter embodiments, the exposed plating corresponds to a terminal on the edge surface of the substrate. In any embodiments, an edge terminal 302 may be disposed on an outermost portion of the substrate edge surface or in a recess of the substrate edge surface. The phrase “edge terminal” as used herein refers interchangeably to either of such varieties.

If desired, an additional electrically conductive plating layer 304 may be formed on the exterior-facing surfaces of edge terminals 302 to facilitate better physical and electrical bonding between the capacitor terminals and the edge terminals. The capacitor itself may then be physically and electrically coupled to the substrate terminals (whether plated or not plated) using solder connections 306.

In some embodiments, an edge terminal may be electrically coupled to more than one substrate conductor, if appropriate for a given application. An example of the latter type of embodiments is illustrated in FIG. 5. Edge terminal 500 of FIG. 5 is electrically coupled to three substrate conductors 504, 506, 508 disposed on different layers inside the substrate. Edge terminal 502 of FIG. 5 is electrically coupled to two substrate conductors 510, 512. If desired, two or more of the substrate conductors that are coupled to a single edge terminal may also be electrically coupled to one another inside the substrate, such as with vias 514 as shown.

Connectivity of Edge-Mounted Capacitors to Die Circuitry and/or to Host Circuitry

As was mentioned above, capacitors 106 may be connected to circuitry of the integrated circuit die and/or to circuitry of a host system PCB in a variety of different ways. In the embodiment of FIG. 2 for example, each terminal of an edge-mounted capacitor is connected by substrate conductors both to an integrated circuit die pad and to a system interconnect terminal disposed on the bottom of the substrate. In the embodiment of FIG. 4, one terminal of an edge-mounted capacitor is connected by a substrate conductor only to an integrated circuit die pad, while the other terminal of the capacitor is connected by a substrate conductor only to a system interconnect terminal on the bottom of the substrate.

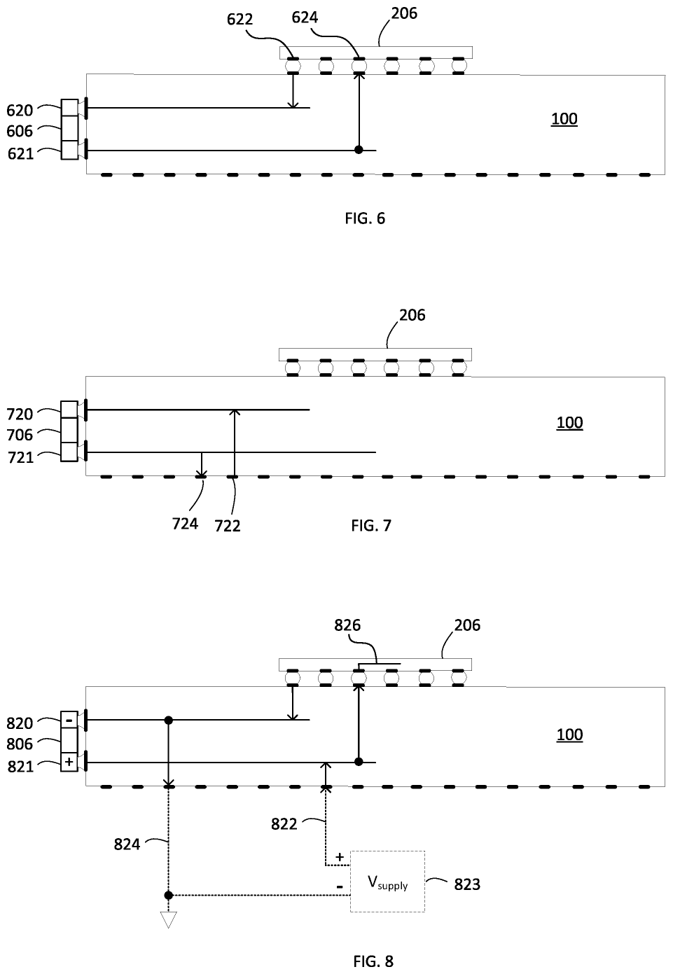

FIGS. 6 and 7 illustrate additional possible ways in which an edge-mounted capacitor may be connected to circuitry of the integrated circuit die and/or to circuitry of a host system PCB. In the embodiment of FIG. 6, each terminal of an edge-mounted capacitor 606 is connected by a substrate conductor only to an integrated circuit die pad (capacitor terminal 620 of the capacitor is connected only to die pad 622, while capacitor terminal 621 is connected only to die pad 624). In the embodiment of FIG. 7, each terminal of an edge-mounted capacitor 706 is connected by a substrate conductor only to a system interconnect terminal (capacitor terminal 720 is connected only to system interconnect terminal 722, while capacitor terminal 721 is connected only to system interconnect terminal 724).

Although the edge-mounted capacitors are shown oriented vertically in the embodiments of FIGS. 2, 6, and 7, and horizontally in the embodiment of FIG. 4, the types of connectivity illustrated in the figures may also be implemented in embodiments in which the edge-mounted capacitors are oriented differently. For example, one or more of the capacitors of FIG. 2, 6, or 7 may be oriented horizontally, and one or more of the capacitors of FIG. 4 may be oriented vertically.

### Edge-Mounted Capacitors as Decoupling Capacitors

In any embodiments, one or more of the edge-mounted capacitors may be connected as a decoupling capacitor. In such embodiments, one terminal of an edge-mounted capacitor is electrically coupled to a power supply node, while the other terminal of the edge-mounted capacitor is electrically coupled to a ground node. The power supply node may be disposed at least partially on the integrated circuit die, or on the host system PCB, or both. Similarly, the ground node may be disposed at least partially on the integrated circuit die, or on the host system PCB, or both. Among the benefits associated with such embodiments are that the edge-mounted capacitors connected as decoupling capacitors can provide superior decoupling of switching noise from the power supply node relative to that provided by conventional techniques. The superior decoupling is due both to the close proximity of the edge-mounted capacitor to the power supply node on the integrated circuit die and to the relatively large capacitance that can be provided by exteriorly mounted discrete capacitors. In some embodiments, the edge mounted capacitor 806 may comprise a polarized capacitor such as an electrolytic capacitor.

FIG. 8 shows one such embodiment by way of example, using the type of connectivity illustrated in the embodiment of FIG. 2. In the embodiment of FIG. 8, one terminal (terminal 821) of an edge-mounted capacitor 806 is connected by a substrate conductor to a power supply node 822, and the other terminal (terminal 820) of the capacitor is connected by a substrate conductor to a ground node 824. In the illustrated embodiment, the power supply node is disposed at least partially inside the integrated circuit die, as shown at 826. The portion 826 disposed inside the die may comprise a power supply rail, for example, from which one or more circuitry subsystems on the integrated circuit die draw power. In the illustrated embodiment, the power supply node is shown connected to a power supply 823 disposed on a host system PCB or elsewhere. In the illustrated embodiment, capacitor 806 is a polarized electrolytic capacitor. In other embodiments, different types of capacitors may be used, including non-polarized capacitors. Similar decoupling capacitor arrangements may be implemented in other embodiments, including those illustrated in FIGS. 4, 6, and 7.

### Coupling Edge-Mounted Capacitors to Data Nodes

Also in any embodiments, at least one of the terminals of an edge-mounted capacitor may be electrically coupled by a substrate conductor to a data node of the integrated circuit die, if desired. The phrase “data node” as used herein refers to a node that carries an electrical signal, as opposed to a power supply node, which does not carry a signal but instead supplies power to circuitry connected to the power supply node. An electrical signal carried on a data node may be, for example, a switching digital signal. Such a switching signal may comprise, for example, an input and/or an output data node configured to input data from an external system into circuitry of the integrated circuit die, or to output data from circuitry of the integrated circuit die to an external system, or both. Connecting an edge-mounted capacitor to such a data node may, for example, enable filtration of noise from the data node or may enable capacitive coupling of the data node to another node on the integrated circuit die or to a node on a host system PCB.

### Connectivity of Edge-Mounted Capacitors to One Another

In embodiments that include more than one edge-mounted capacitor, the capacitors may be coupled to one other, or not coupled to one another, in various ways. FIG. 9 illustrates examples of several such possibilities for purposes of explanation. In FIG. 9, substrate 100 includes plural edge-mounted capacitors 900, 902, 904, and 906. The terminals of capacitor 900 are coupled to substrate 100 via respective terminals of edge terminal pair 901. The terminals of capacitor 902 are coupled to the substrate via respective terminals of edge terminal pair 903. The terminals of capacitor 904 are coupled to the substrate via respective terminals of edge terminal pair 905, and the terminals of capacitor 906 are coupled to the substrate via respective terminals of edge terminal pair 907. Each of the edge terminals in the edge terminal pairs is connected to one or more substrate conductors disposed on or inside the substrate. In the illustrated embodiment, capacitors 900 and 904 are effectively connected in parallel with one another inside the substrate by virtue of their connections to substrate conductors 908 and 910. Capacitor 902, however, has only one of its terminals connected to a same node as capacitors 900 and 904 (via a connection to substrate conductor 910), while its other terminal is connected to an electrically independent substrate conductor 912. Capacitor 906 is electrically independent from all of the other capacitors. Its terminals are connected to substrate conductors 916 and 918, neither of which is connected to any of the other substrate conductors. As these examples illustrate, embodiments may include a variety of different connectivity arrangements for the edge-mounted capacitors as appropriate or desirable for a given application. By connecting multiple edge-mounted capacitors in parallel, for example, additional capacitance may be provided for decoupling switching noise from a single power supply node on an integrated circuit die that is coupled to the substrate.

It should be noted that, while the substrate conductors of FIG. 9 are illustrated as wires for the sake of explanation, in various embodiments any or all of the substrate conductors may comprise metal planes or partial planes formed on layers inside the substrate.

### Edge-Mounted Capacitors on Multiple Edge Surfaces

As the example embodiments of FIGS. 1, 9, 10, and 11 all illustrate, edge terminal pairs may be provided on two, three, or four edge surfaces of a substrate, if desired. In such embodiments, one or more edge-mounted capacitors may be mounted on each of the two, three, or four edge surfaces, with terminals of each capacitor electrically coupled to respective terminals of the edge terminal pairs.

### Capacitor Orientations

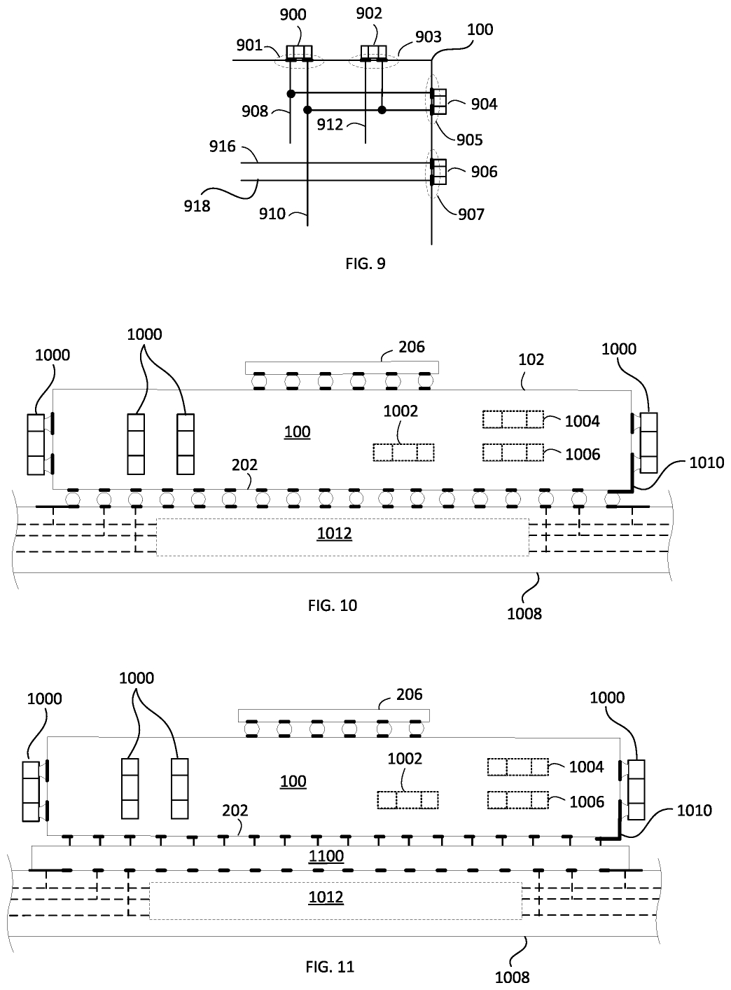

The axial orientations of the capacitors mounted on the substrate edge surfaces need not all be the same. For example, as the embodiments of FIGS. 10 and 11 illustrate, one or more capacitors 1000 may be mounted vertically (as shown), while one or more other capacitors 1002, 1004, 1006 may be mounted horizontally (also as shown). Moreover, some or all of the edge-mounted capacitors may be arranged directly one over the other, as illustrated by the arrangement of capacitors 1004 and 1006. In the latter arrangement, capacitor 1004 is closer to top surface 102 than is capacitor 1006, while capacitor 1006 is closer to bottom surface 202 than is capacitor 1004, and the bodies of the two capacitors are substantially aligned in the vertical direction.

### Attachment of Substrate to Host System PCB

Referring again now to FIG. 10, substrate 100 may be attached to a PCB 1008 of a host system by directly soldering the system interconnect terminals of the substrate to corresponding lands, pads, or pins disposed on the host system PCB.

Or, as FIG. 11 illustrates, substrate 100 may be attached to PCB 1008 indirectly through a suitable socket connector 1100. Such a socket may take any of a variety of known forms. For example, the socket may comprise an LGA, a BGA, or a PGA socket.

In either type of embodiment, attachment of the substrate to the PCB enables circuitry on integrated circuit die 206 to be electrically coupled to circuitry 1012 on the PCB, which may itself be coupled to other circuitry or components disposed on the PCB or elsewhere. As the dashed lines in FIGS. 10 and 11 illustrate, PCB circuitry 1012 may comprise one or more conductive layers formed on or inside the PCB.

### External Substrate Conductors

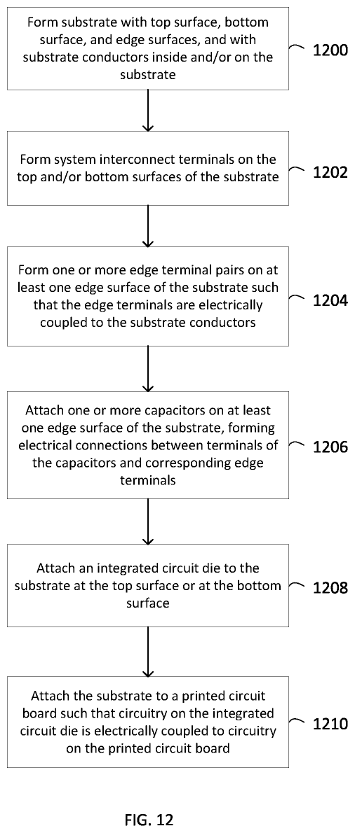

As FIGS. 11 and 12 also illustrate, at 1010, in some embodiments one or more of the substrate conductors may be disposed on an external surface of the substrate.

### Method of Manufacture

Embodiments as described above may be manufactured in accordance with an example method generally illustrated at FIG. 12.

At step 1200, a substrate is formed having a generally planar top surface, a generally planar bottom surface oriented substantially parallel to the top surface, and edge surfaces disposed along the periphery of the substrate and oriented substantially orthogonally to the top surface and to the bottom surface. The substrate is formed such that one or more substrate conductors are disposed inside and/or on the substrate. For example, the substrate conductors may include one or more conductive metal plane layers formed on or inside the substrate, as generally described above.

At step 1202, system interconnect terminals are formed on the top surface of the substrate, or on the bottom surface, or on both surfaces. The system interconnect terminals are configured to be electrically coupled to circuitry on a host system PCB, either directly or through a connector such as a socket. The system interconnect terminals may take any of a variety of known forms including, for example, lands, pads, or pins. Each of the system interconnect terminals is electrically coupled to one or more of the substrate conductors.

At step 1204, one or more edge terminal pairs are formed on at least one of the edge surfaces of the substrate. The edge terminals may be formed in accordance with any of several techniques generally described above including, for example, by etching, by deposition, or by plating through holes of the substrate and removing portions of the through holes to expose plating at the edge of the substrate. Each of the edge terminals is electrically coupled to one or more of the substrate conductors.

At step 1206, one or more capacitors are attached to one or more of the substrate edge surfaces by forming electrical connections (e.g. by soldering) between terminals of the capacitors and corresponding edge terminals on the substrate. In some embodiments, the capacitors may comprise surface mount capacitors.

At step 1208, an integrated circuit die is attached to the substrate. In various embodiments, the integrated circuit die may be attached at the top surface of the substrate or at the bottom surface of the substrate. Pads on the integrated circuit die are electrically coupled to one or more of the substrate conductors using any of several known techniques including, for example, by means of solder balls or by wire bonding.

At step 1210, the substrate assembly is attached to a PCB in a manner such that circuitry on the integrated circuit die is electrically coupled to circuitry on the printed circuit board. Attachment of the substrate assembly to the PCB may be accomplished using any of several known techniques including, for example, by directly soldering lands or pads on the substrate to corresponding lands or pads on the PCB, or by soldering a socket to the PCB and then inserting the substrate into the socket. In the latter embodiments, the socket may comprise any of several known types including, for example, PGA, LGA, or BGA sockets.

Multiple specific embodiments are described above and in the appended claims. The embodiment descriptions are provided by way of example and illustration. Persons having skill in the art and having reference to this disclosure will perceive various utilitarian combinations, modifications, and generalizations of the features and characteristics of the embodiments so described. For example, steps in methods described herein may generally be performed in any order, and some steps may be omitted, while other steps may be added, except where the context clearly indicates otherwise. Similarly, components in structures described herein may be arranged in different positions or locations, and some components may be omitted, while other components may be added, except where the context clearly indicates otherwise. The scope of the disclosure is intended to include all such combinations, modifications, and generalizations, as well as their equivalents.

What is claimed is:

1. An apparatus, comprising:
a substrate having a top surface and a bottom surface, wherein each of the top surface and the bottom surface is generally planar and is oriented substantially parallel to the other, wherein at least one of the top surface and the bottom surface includes a die mounting area, and wherein at least one of the top surface and the bottom surface comprises system interconnect terminals;
a first substrate edge surface disposed along a first peripheral end of the substrate and oriented substantially orthogonally to the top surface and to the bottom surface;
a first pair of conductive edge terminals disposed on the first substrate edge surface, and a first pair of substrate conductors disposed on or inside the substrate, wherein each of the edge terminals is electrically coupled to a respective one of the substrate conductors;
a first capacitor attached exteriorly to the substrate at the first substrate edge surface such that terminals of the first capacitor are electrically coupled to respective ones of the edge terminals; and
an integrated circuit die comprising electrically conductive die pads and attached to the substrate at the die mounting area.

2. The apparatus of claim 1, wherein:
the first capacitor comprises a surface mount capacitor.

3. The apparatus of claim 2, wherein:
the first capacitor comprises opposite ends, such that the opposite ends define a capacitor axis extending from one of the opposite ends to the other;
the terminals of the first capacitor are disposed at respective ones of the opposite ends; and
the capacitor axis is oriented substantially parallel to the first substrate edge surface.

4. The apparatus of claim 3, wherein:
the capacitor axis is oriented substantially perpendicular to a plane of the top surface and to a plane of the bottom surface.

5. The apparatus of claim 3, wherein:
the capacitor axis is oriented substantially parallel to a plane of the top surface and to a plane of the bottom surface.

6. The apparatus of claim 1, wherein:
at least one of the edge terminals is directly coupled to more than one substrate conductor disposed on or inside the substrate.

7. The apparatus of claim 1, wherein:
one of the first substrate conductors is electrically coupled to one of the die pads; and
the other of the first substrate conductors is electrically coupled to one of the system interconnect terminals.

8. The apparatus of claim 1, wherein:
one of the first substrate conductors is electrically coupled to one of the die pads; and
the other of the first substrate conductors is electrically coupled to a different one of the die pads.

9. The apparatus of claim 1, wherein:
one of the first substrate conductors is electrically coupled to one of the system interconnect terminals; and
the other of the first substrate conductors is electrically coupled to a different one of the system interconnect terminals.

10. The apparatus of claim 1, wherein:
one of the first substrate conductors is electrically coupled to a data node of the integrated circuit die through a data die pad on the integrated circuit die.

11. The apparatus of claim 1, wherein:
one of the first substrate conductors is electrically coupled to a power supply node; and
the other of the first substrate conductors is electrically coupled to a ground node.

12. The apparatus of claim 11, wherein:
the power supply node is disposed at least partially inside the integrated circuit die; and
the ground node is electrically coupled to one of the system interconnect terminals.

13. The apparatus of claim 1, further comprising:
a second pair of conductive edge terminals disposed on the first substrate edge surface, and a second pair of substrate conductors disposed on or inside the substrate, wherein each of the edge terminals in the second pair of edge terminals is electrically coupled to a respective one of the substrate conductors in the second pair of substrate conductors; and
a second capacitor attached exteriorly to the substrate at the first substrate edge surface such that terminals of the second capacitor are electrically coupled to respective ones of the edge terminals in the second pair of edge terminals.

14. The apparatus of claim 13, wherein:
opposite ends of the first capacitor define a first capacitor axis extending between them;
opposite ends of the second capacitor define a second capacitor axis extending between them; and
the first capacitor axis and the second capacitor axis are not oriented in a same direction.

15. The apparatus of claim 13, wherein:
the first capacitor and the second capacitor are disposed one over the other such that the first capacitor is closer to the top surface of the substrate and the second capacitor is closer to the bottom surface of the substrate.

16. The apparatus of claim 13, wherein:
the first pair of substrate conductors and the second pair of substrate conductors comprise a same pair of substrate conductors.

17. The apparatus of claim 1, further comprising:
second, third, and fourth substrate edge surfaces disposed respectively along second, third, and fourth peripheral ends of the substrate and each oriented substantially orthogonally to the top surface and to the bottom surface;
second, third, and fourth pairs of edge terminals disposed respectively on the second, third, and fourth substrate edge surfaces; and
second, third, and fourth capacitors attached exteriorly to the substrate at the second, third, and fourth substrate edge surfaces, respectively, such that terminals of the second, third, and fourth capacitors are electrically coupled to respective ones of the second, third, and fourth pairs of edge terminals.

18. A method, comprising:
forming a substrate such that the substrate has a generally planar top surface, a generally planar bottom surface oriented substantially parallel to the top surface, and an edge surface disposed along a periphery of the substrate and oriented substantially orthogonally to the top surface and to the bottom surface;
forming system interconnect terminals on at least one of the top surface and the bottom surface;
forming a pair of edge terminals on the edge surface such that the each edge terminal is electrically coupled to a respective substrate conductor disposed on or inside the substrate;
attaching an integrated circuit die to the substrate at the top surface or at the bottom surface; and
attaching a capacitor exteriorly to the substrate on the edge surface, such that one terminal of the capacitor is electrically coupled to one of the edge terminals of the pair of edge terminals and another terminal of the capacitor is electrically coupled to the other edge terminal of the pair of edge terminals.

19. The method of claim 18, further comprising:
attaching the substrate to a printed circuit board such that circuitry on the integrated circuit die is electrically coupled to circuitry on the printed circuit board.

20. The method of claim 19, wherein:
attaching the substrate to the printed circuit board comprises attaching the substrate to the printed circuit board through a socket.

21. The method of claim 18, further comprising:
forming plural pairs of edge terminals on the edge surface; and
attaching plural capacitors exteriorly to the substrate on the edge surface, such that each of the plural capacitors is electrically coupled to a respective one of the plural pairs of edge terminals.

22. The method of claim 18, wherein:
attaching the capacitor exteriorly to the substrate on the edge surface comprises attaching a surface mount capacitor exteriorly to the substrate on the edge surface.
